(19) United States
(12) Patent Application Publication
(10) Pub. No.: US 2010/0012994 A1
(43) Pub. Date: Jan. 21, 2010

(54) SEMICONDUCTOR STORAGE DEVICE

(75) Inventors: Tohru OZAKI, Tokyo (JP); Iwao KUNISHIMA, Yokohama-shi (JP); Yoshinori KUMURA, Albany, CA (US)

Correspondence Address: KNOBBE MARTENS OLSON & BEAR LLP, 2040 MAIN STREET, FOURTEENTH FLOOR, IRVINE, CA, 92614, US

(73) Assignee: Kabushiki Kaisha Toshiba, Tokyo (JP)

(21) Appl. No.: 12/504,439

(22) Filed: Jul. 16, 2009

(30) Foreign Application Priority Data
Jul. 16, 2008 (JP) 2008-184735

(51) Int. Cl. H01L 27/115; H01L 29/94

(52) U.S. Cl. 257/295; 257/E27.104; 257/296; 257/E29.345

(57) ABSTRACT

A semiconductor storage device has the ferroelectric capacitor has: a capacitor film formed above the MOS transistor with an interlayer insulating film interposed therebetween; a first capacitor electrode electrically connected to a source region of the MOS transistor and formed in contact with one side wall of the capacitor film; and a second capacitor electrode electrically connected to a drain region of the MOS transistor and formed in contact with the other side wall of the capacitor film, and the capacitor film is composed of a film stack including a plurality of films including a first insulating film intended to orient a film formed on an upper surface thereof in a predetermined direction and a ferroelectric film formed on the first insulating film to be oriented in a direction perpendicular to the semiconductor substrate.

### CROSS-REFERENCE TO RELATED APPLICATION

This application is based upon and claims the benefit of priority from the prior Japanese Patent Application No.2008-184735, filed on Jul. 16, 2008, the entire contents of which are incorporated herein by reference.

### BACKGROUND OF THE INVENTION

1. Field of the Invention

The present invention relates to a semiconductor storage device and is applied to a ferroelectric random access memory (FeRAM), for example.

2. Background Art

Among other nonvolatile semiconductor memories, the ferroelectric random access memory (FeRAM) incorporating a ferroelectric capacitor has been attracting attention in recent years.

For the ferroelectric random access memory, in view of the area penalty, a three-dimensional cell structure has been proposed in which a ferroelectric film is disposed between wall-like electrodes formed on the source and drain of a cell selection transistor to form a plate capacitor parallel to the transistor on the gate electrode of the transistor.

In particular, a method of manufacturing the three-dimensional cell has been proposed which involves forming a <001>-oriented PZT (Pb(ZrₓTi₁₋ₓ)O₃) film on a seed layer, etching a part of the PZT film in which an electrode is to be formed to form a contact hole, and burying an electrode in the contact hole (see N. Nagel et al., VLSI Technology, pp. 146 (2004), for example).

However, in the three-dimensional structure described above, grains of the PZT film oriented in the Z direction (the direction perpendicular to the plane of the substrate) on the seed layer have a size of about 100 nm. Therefore, in the case of 100-nm-generation memories, many cells have only one grain when viewed in the Z direction.

In addition, PZT grown on the seed layer forms a continuous crystal in the Z direction, and thus, many cells have a capacitor formed by one grain under rigid layout limitations.

In such a circumstance, provided that the direction of the current of the capacitor (the direction parallel to the plane of the substrate) is the X direction, various crystal faces can appear in the X direction since the orientation is in the Z direction.

In particular, in the case where the <100> face appears in the X direction, the capacitor has no polarization, and therefore, there is a problem that the cell is intrinsically unserviceable.

### SUMMARY OF THE INVENTION

According to one aspect of the present invention, there is provided: a semiconductor storage device, comprising:

an MOS transistor formed on a semiconductor substrate; and

a ferroelectric capacitor disposed above the MOS transistor and connected in parallel with the MOS transistor,

wherein the ferroelectric capacitor has:

a capacitor film formed above the MOS transistor with an interlayer insulating film interposed therebetween;

a first capacitor electrode electrically connected to a source region of the MOS transistor and formed in contact with one side wall of the capacitor film; and

a second capacitor electrode electrically connected to a drain region of the MOS transistor and formed in contact with the other side wall of the capacitor film, and

the capacitor film is composed of a film stack including a plurality of films including a first insulating film intended to orient a film formed on an upper surface thereof in a predetermined direction and a ferroelectric film formed on the first insulating film to be oriented in a direction perpendicular to the semiconductor substrate.

### BRIEF DESCRIPTION OF THE DRAWINGS

FIG. 1 is a schematic plan view showing a pattern of a ferroelectric capacitor and its vicinity of a memory cell of a semiconductor storage device 100 according to a first embodiment of the present invention;

FIG. 2 is a diagram that includes cross-sectional views of the semiconductor storage device 100 shown in FIG. 1 taken along the lines A-A, B-B and C-C;

FIG. 3 is a diagram that includes cross-sectional views taken along the lines A-A, B-B and C-C in FIG. 1, illustrates different step in a method of manufacturing the semiconductor storage device 100 according to the first embodiment of the present invention;

FIG. 4 is a diagram that includes cross-sectional views taken along the lines A-A, B-B and C-C in FIG. 1, illustrates a step in a method of manufacturing the semiconductor storage device 100 according to the first embodiment of the present invention, and is continuous from FIG. 3;

FIG. 5 is a diagram that includes cross-sectional views taken along the lines A-A, B-B and C-C in FIG. 1, illustrates a step in a method of manufacturing the semiconductor storage device 100 according to the first embodiment of the present invention, and is continuous from FIG. 4;

FIG. 6 is a diagram that includes cross-sectional views taken along the lines A-A, B-B and C-C in FIG. 1, illustrates a step in a method of manufacturing the semiconductor storage device 100 according to the first embodiment of the present invention, and is continuous from FIG. 5;

FIG. 7 is a diagram that includes cross-sectional views taken along the lines A-A, B-B and C-C in FIG. 1, illustrates a step in a method of manufacturing the semiconductor storage device 100 according to the first embodiment of the present invention, and is continuous from FIG. 6;

FIG. 8 is a diagram that includes cross-sectional views taken along the lines A-A, B-B and C-C in FIG. 1, illustrates a step in a method of manufacturing the semiconductor storage device 100 according to the first embodiment of the present invention, and is continuous from FIG. 7;

FIG. 9 is a diagram that includes cross-sectional views taken along the lines A-A, B-B and C-C in FIG. 1, illustrates a step in a method of manufacturing the semiconductor storage device 100 according to the first embodiment of the present invention, and is continuous from FIG. 8;

FIG. 10 is a diagram that includes cross-sectional views taken along the lines A-A, B-B and C-C in FIG. 1, illustrates a step in a method of manufacturing the semiconductor storage device 100 according to the first embodiment of the present invention, and is continuous from FIG. 9;

FIG. 11 is a diagram that includes cross-sectional views taken along the lines A-A, B-B and C-C in FIG. 1, illustrates a step in a method of manufacturing the semiconductor storage device 100 according to the first embodiment of the present invention, and is continuous from FIG. 10;

FIG. 12 is a diagram that includes cross-sectional views taken along the lines A-A, B-B and C-C in FIG. 1, illustrates a step in a method of manufacturing the semiconductor storage device 100 according to the first embodiment of the present invention, and is continuous from FIG. 11;

FIG. 13 is a diagram that includes cross-sectional views taken along the lines A-A, B-B and C-C in FIG. 1, illustrates a step in a method of manufacturing the semiconductor storage device 100 according to the first embodiment of the present invention, and is continuous from FIG. 12; and

FIG. 14 includes cross-sectional views of a ferroelectric capacitor and its vicinity of a memory cell of a semiconductor storage device 200 according to the second embodiment of the present invention.

### DETAILED DESCRIPTION

In the following, embodiments of the present invention will be described with reference to the drawings.

### First Embodiment

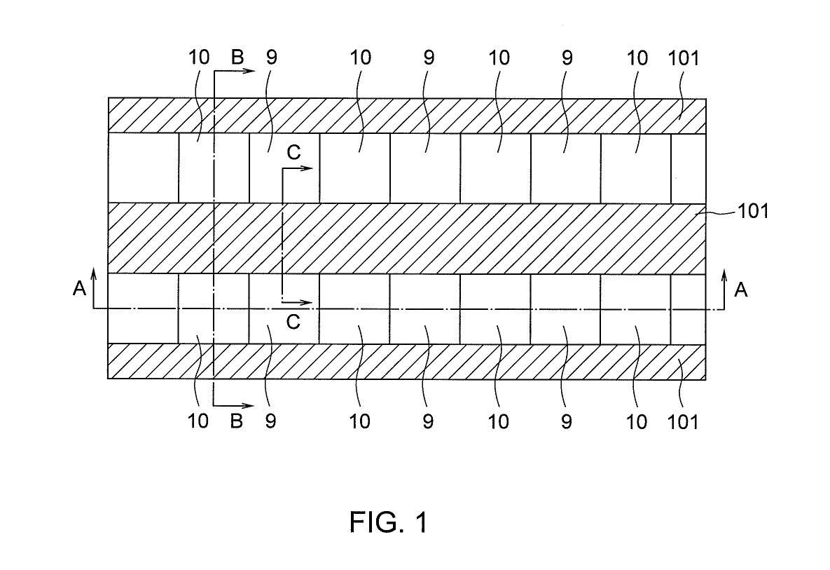

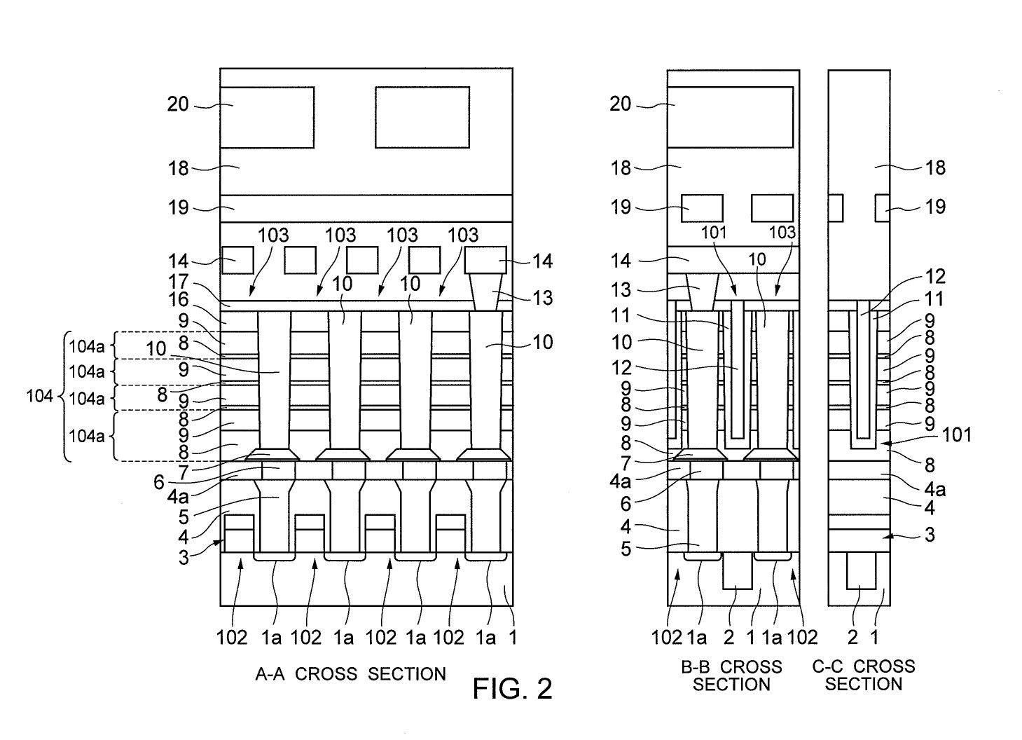

FIG. 1 is a schematic plan view showing a pattern of a ferroelectric capacitor and its vicinity of a memory cell of a semiconductor storage device 100 according to a first embodiment of the present invention. FIG. 2 includes cross-sectional views of the semiconductor storage device 100 shown in FIG. 1 taken along the lines A-A, B-B and C-C.

As shown in FIGS. 1 and 2, the semiconductor storage device 100, which is a ferroelectric random access memory, has MOS transistors 102 disposed on a semiconductor substrate and ferroelectric capacitors 103 disposed above the MOS transistors 102 and connected in parallel with the MOS transistors 102.

The MOS transistors 102 and the ferroelectric capacitors 103 form a memory cell.

Each MOS transistor 102 has a gate insulating film (not shown) formed on the semiconductor substrate 1, which is a silicon substrate or the like, a gate electrode 3 formed on the gate insulating film, and a diffusion layer la that is formed in a device region in such a manner that the gate electrode 3 is sandwiched between the diffusion layers la of adjacent MOS transistors 102.

Adjacent device regions are isolated from each other by a device isolation insulating film (shallow trench isolation (STI) film) 2.

The ferroelectric capacitor 103 has a capacitor film 104 and a capacitor electrode 10.

The capacitor film 104 is formed above the MOS transistor 102 with an interlayer insulating films 4, 4a interposed therebetween. The capacitor film 104 is isolated from the capacitor film 104 of the adjacent ferroelectric capacitor 103 by an isolation pattern 101 formed above the device isolation insulating film 2.

The capacitor film 104 is a film stack including a plurality of films 104a each including an insulating film 8 that is a seed layer intended to orient a film formed on the upper surface thereof in a predetermined direction and a ferroelectric film 9 that is formed on the insulating film 8 and oriented in a direction perpendicular to a semiconductor substrate 1.

The ferroelectric film 9 is a PZT (Pb(ZrₓTi₁₋ₓ)O₃) film, a BIT (Bi₄Ti₃O₁₂) film, a BLT film, or an SBT (SrBi₂Ta₂O₉) film, for example. The ferroelectric film 9 is oriented in a direction perpendicular to the semiconductor substrate 1, such as the <1, 1, 1> orientation, the <1, 0, 0> orientation and the <0, 1, 0> orientation. The ferroelectric film 9 has the shape of a flat plate parallel to the plane of the semiconductor substrate.

As described above, for the conventional ferroelectric capacitor, provided that the direction of the current of the capacitor (the direction parallel to the plane of the substrate) is the X direction, various crystal faces can appear in the X direction since the orientation is in the Z direction. In particular, in the case where the <100> face appears in the X direction, the capacitor has no polarization, and therefore, there is a problem that the cell is intrinsically unserviceable.

However, according to this embodiment, as described above, the capacitor film 104 includes a plurality of films 104a each including the insulating film 8 serving as a seed layer and the ferroelectric film 9 that is formed on the insulating film 8 and oriented in the direction perpendicular to the semiconductor substrate 1.

As a result, in each ferroelectric film 9, various crystal faces appear in the X direction. That is, each capacitor film 104 has ferroelectric films 9 having different crystal faces appearing in the X direction.

As a result, the possibility of occurrence of the intrinsically unserviceable cell can be substantially reduced. In addition, variations in polarization characteristics of the capacitor film 104 of each ferroelectric capacitor 103 can be reduced.

The number of films 104a in the stack film is preferably five or six. However, the number of films 104a stacked can be adjusted as required. Increasing the number of films 104a stacked can further reduce variations in polarization characteristics of the capacitor film 104 of each ferroelectric capacitor 103.

The capacitor electrode 10 is electrically connected to a source region (the diffusion layer 1a) of the MOS transistor 102 and formed in contact with one side wall of the capacitor film 104. Similarly, an adjacent capacitor electrode 10 is electrically connected to a drain region (the diffusion layer 1a) of the MOS transistor 102 and is formed in contact with the other side wall of the capacitor film 104. That is, the capacitor film 104 is sandwiched between two capacitor electrodes. The capacitor electrode 10 is made of Ir, IrO₂, SRO or Ru, for example.

Between the capacitor films 104 of the adjacent ferroelectric capacitors 103 connected in parallel with the adjacent MOS transistors 102 isolated by the device isolation insulating films 102, respectively, an insulating film 12 having a lower dielectric constant than the ferroelectric film is formed. The insulating film 12 is made of SiO₂, for example. An alumina film 11 serving as a protective film is formed between the insulating film 12 and the ferroelectric capacitor 103. The insulating film 12 and the alumina film 11 form the isolation pattern 101 described above.

In addition, a plug 5 is formed on each of the source region and the drain region (the diffusion layer 1a) of the MOS transistor 102.

In addition, a tungsten plug 6 is formed on each contact plug 5.

In addition, a pedestal electrode 7 is formed on each tungsten plug 6. The pedestal electrode 7 has a larger diameter than the tungsten plug 6. The capacitor electrode 10 is formed on the pedestal electrode 7. The pedestal electrode 7 has a stack structure, such as TiAIN/Ir.

Inserting the pedestal electrode between the capacitor electrode 10 and the tungsten plug 6 improves the margin for misalignment between the capacitor electrode 10 and the tungsten plug 6.

In addition, a buffer layer 16 for shielding the ferroelectric film 9 from hydrogen or the like is formed on the capacitor film 104. The buffer layer 16 is an alumina film, for example.

An insulating film 17 is formed on the buffer layer 16 and the capacitor electrode 10.

In addition, a plate line 14 is formed in an interlayer insulating film 18 on the insulating film 17. The plate line 14 is connected to the capacitor electrode 10 via the tungsten plug 13.

In addition, above the plate line 14, a bit line 19 electrically connected to the gate electrode 3 of the MOS transistor 102 and a plate line 20 electrically connected to the plate line 14 are disposed.

As described above, since the semiconductor storage device 100 has divided grains in the Z direction, the possibility of appearance of the (100) face in the X direction can be substantially reduced. In addition, an average orientation can be achieved in the X direction. Therefore, in the case of the three-dimensional cell structure, variations in polarization among the cells can be substantially reduced.

Next, an operation of the memory cell of the semiconductor storage device 100 configured as described above will be described.

In writing, in the memory cell, an MOS transistor 102 is selected via the word line connected to the gate electrode 3, and a voltage is applied across the plate line 14 and the bit line 19 to polarize the ferroelectric capacitor 103.

As described above, each ferroelectric film 9 has different crystal face in the X direction. That is, each capacitor film 104 includes ferroelectric films 9 having different crystal faces in the X direction.

Thus, the possibility of occurrence of the intrinsically unserviceable cell can be substantially reduced. Furthermore, variations in polarization characteristics of the capacitor film 104 of each ferroelectric capacitor 103 can be reduced.

On the other hand, in reading, an MOS transistor 102 is selected via the word line, and it is determined whether the MOS transistor 102 is in the “1” state or the “0” state according to whether a current due to polarization reversal flows between the plate line 14 and the bit line 19.

Next, a method of manufacturing the semiconductor storage device 100 configured as described above will be described.

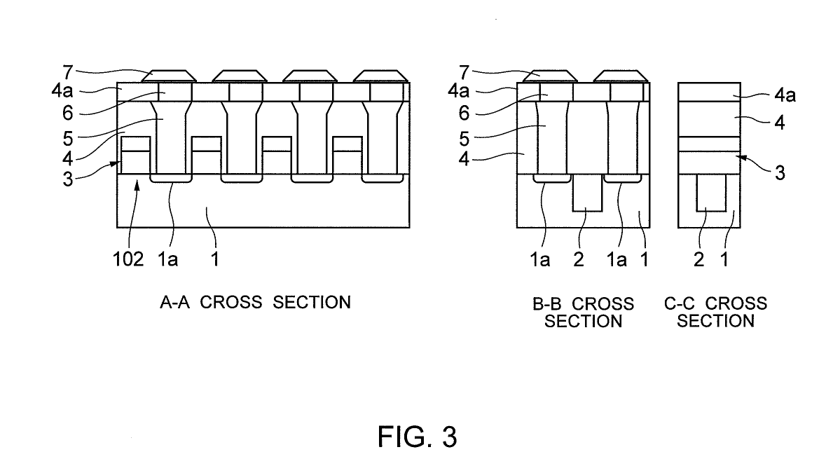

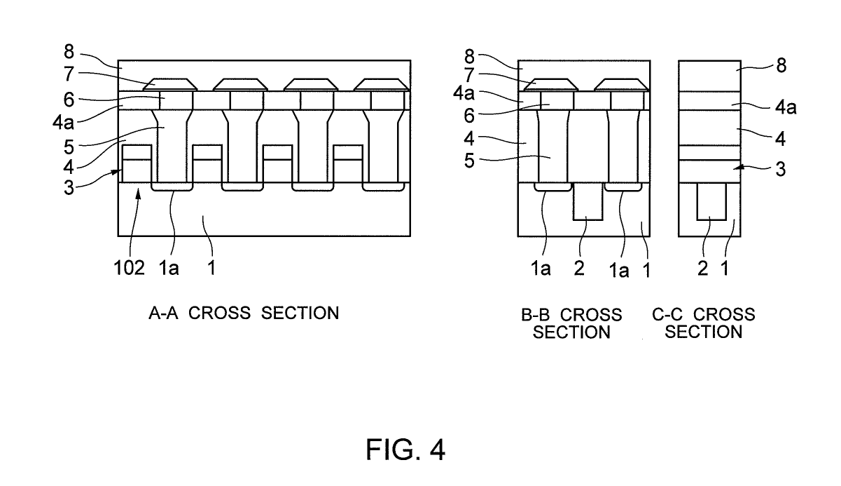

FIGS. 3 to 13, each of which includes cross-sectional views taken along the lines A-A, B-B and C-C in FIG. 1, illustrate different steps in a method of manufacturing the semiconductor storage device 100 according to the first embodiment of the present invention.

First, the MOS transistor 102 is formed on the semiconductor substrate 1. Then, the contact plug 5 is formed of a doped polysilicon, and the tungsten plug is formed on the contact plug 5. That is, the contact plug 5 and the tungsten plug 6 connected to the diffusion layer la are formed in the interlayer insulating films 4 and 4a, respectively.

Then, a layer stack TiAIN/Ir is deposited by physical vapor deposition (PVD) and processed to form the pedestal electrode (FIG. 3).

Then, an alumina layer is deposited to form the insulating film 8 serving as a seed layer by atomic layer deposition (ALD), a combination of sputtering and ALD, or the like.

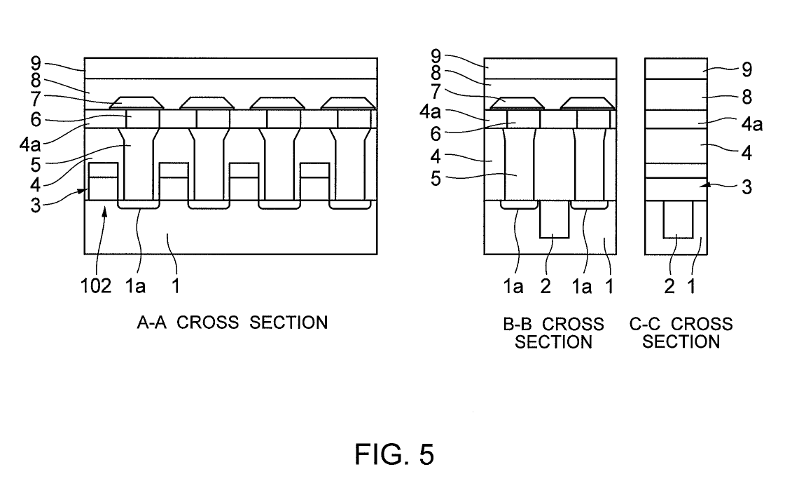

Then, in this example, a PZT film is deposited by MOCVD and crystallized to form the ferroelectric film 9 (FIG. 5).

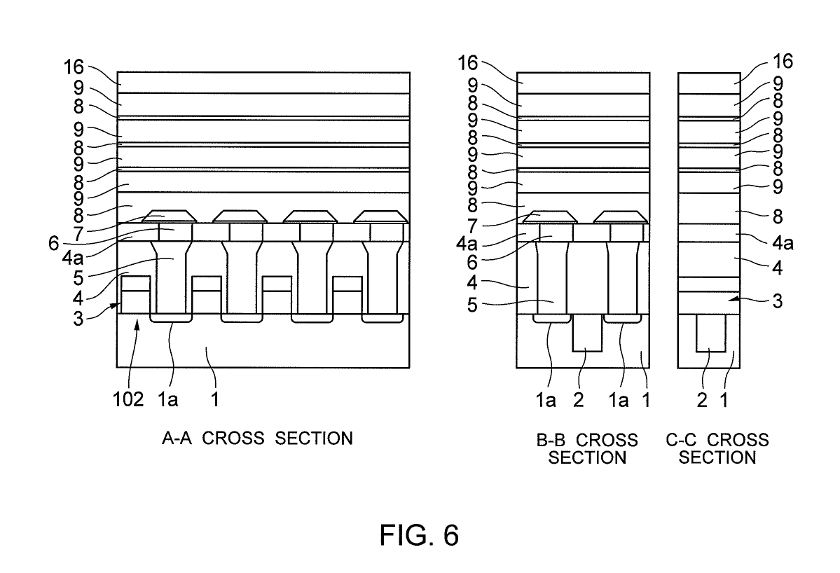

Furthermore, stacking of the insulating film 8 and the ferroelectric film 9 is carried out a plurality of times (preferably four to six times) to form the stack structure of the insulating films 8 and the ferroelectric films 9. Then, an alumina film is formed on the stack structure by sputtering or the like to form the buffer layer 16 (FIG. 6).

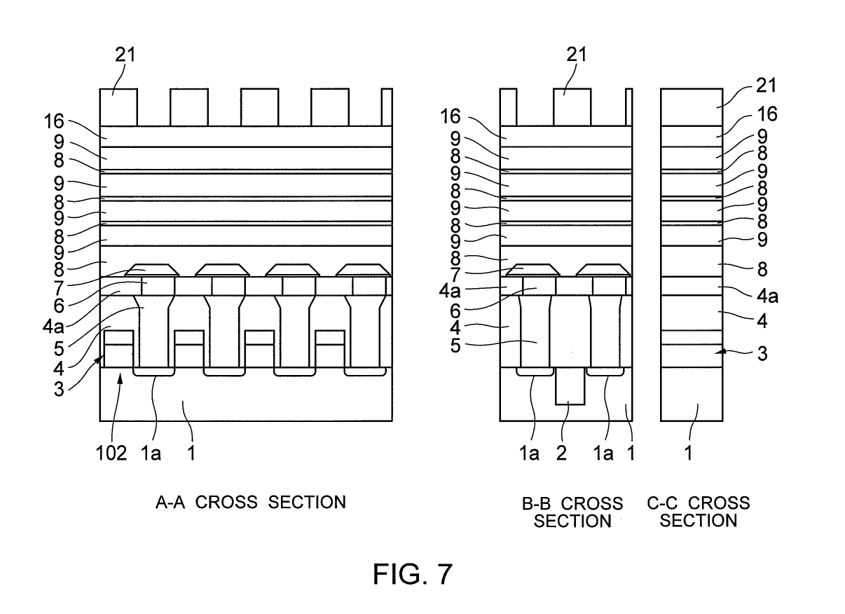

Then, a mask member made of a material, such as Ir, that has a low etching rate for reactive ion etching (RIE) using a Cl-based gas is deposited. Then, the mask member is processed to form a mask 21 for processing the stack structure (FIG. 7).

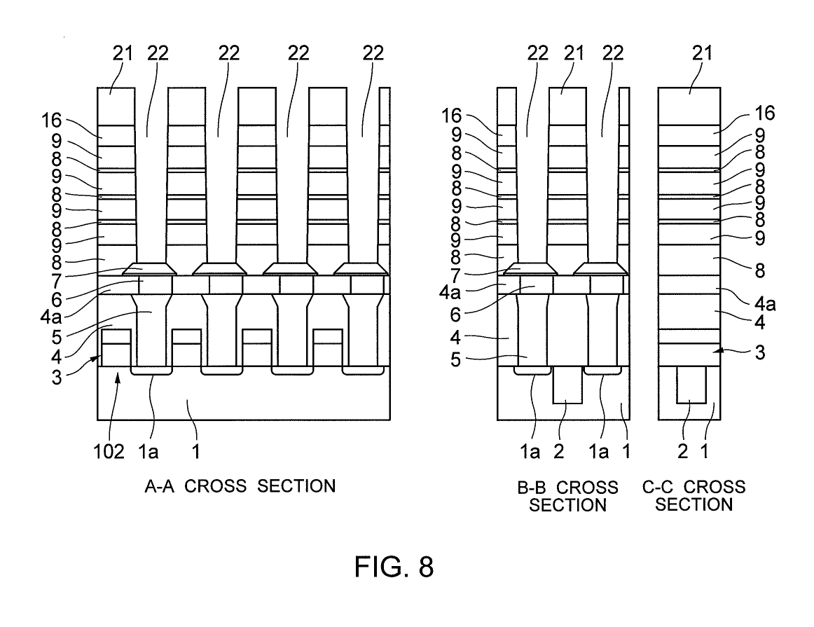

Then, the stack structure (the stack of the alumina layers and the PZT films, in this example) is etched by RIE using a Cl-based gas or BCl-based gas, for example, to form a contact hole 22 (FIG. 8).

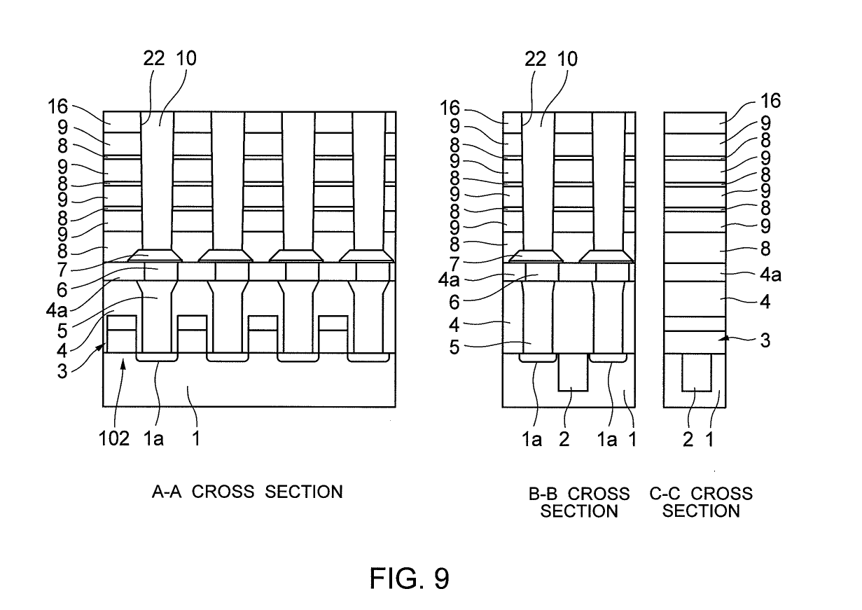

Then, the contact hole 22 is filled with Ir or Ru by chemical vapor deposition (CVD). Then, the entire surface is etched back by chemical mechanical polishing (CMP) or RIE. In this way, the capacitor electrode 10 is formed in the contact hole 22 (FIG. 9).

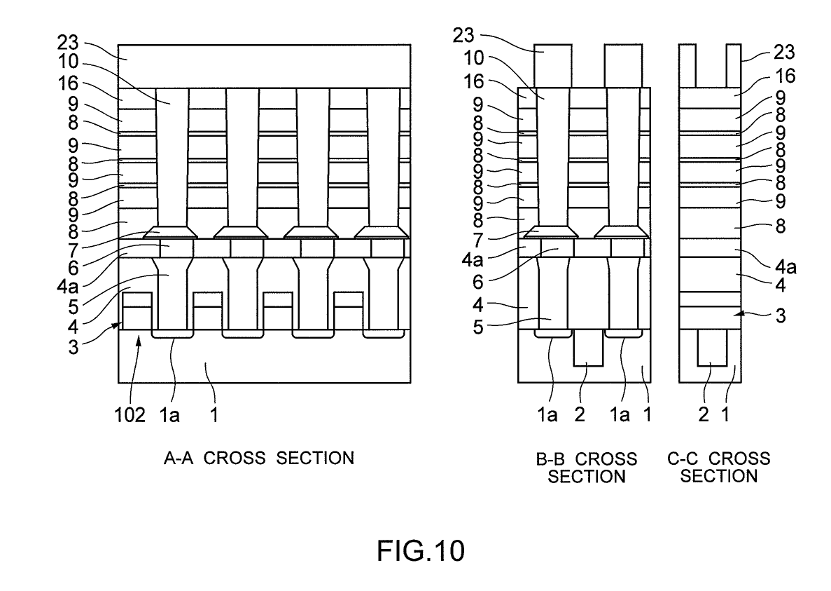

Then, a mask member made of a material, such as Ir, that has a low etching rate for a Cl-based gas is deposited. Then, the mask member is processed to form a mask 23 for processing the stack structure that is intended to form a groove in the region of the stack structure between the electrodes that is not used as the capacitor (FIG. 10).

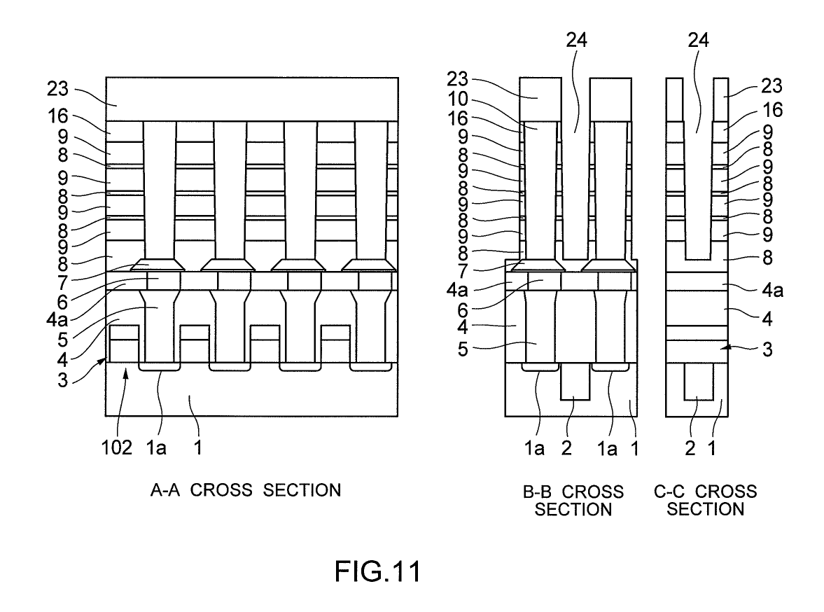

Then, using the mask for processing the stack structure, the stack structure (the stack of the alumina layers and the PZT films, in this example) is etched by RIE using a Cl-based gas or BCl-based gas, for example, to form a groove 24 (FIG. 11).

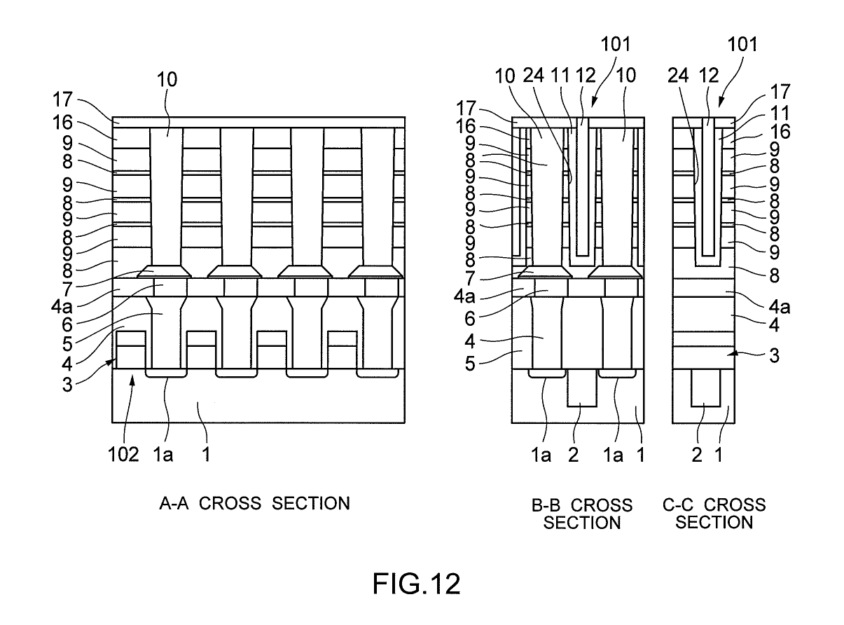

Then, the alumina film 11 is formed in the groove 24 by ALD. Furthermore, the groove 24 is filled with SiO₂ by plasma chemical vapor deposition (PCVD) or the like to form the insulating film 12. In this way, the isolation pattern 101 is formed (FIG. 12).

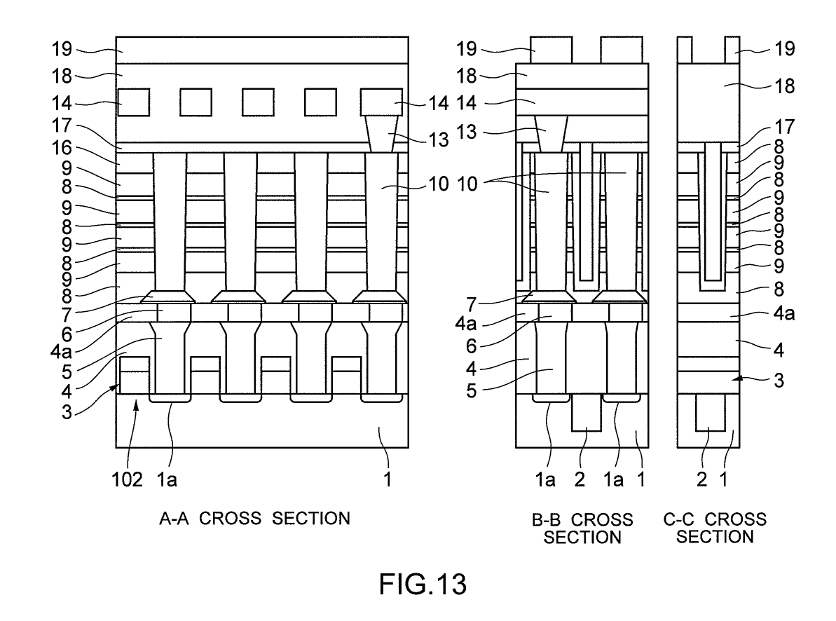

Then, the insulating film 17 is formed on the buffer layer 16 and the capacitor electrode 10, and then, the tungsten plug 13 is formed. Furthermore, the plate line 14 and the bit line 19 are formed by a wiring process, such as AL-RIE method and Cu damascene method (FIG. 13). Furthermore, the plate line 20 is formed to complete the semiconductor storage device 100 shown in FIG. 2.

In this embodiment, as described above, the capacitor film 104 includes a stack of a plurality of films 104a each including the insulating film 8 serving as a seed layer and the ferroelectric film 9 that is formed on the insulating film 8 to be oriented in a direction perpendicular to the semiconductor substrate 1.

As a result, the semiconductor storage device 100 has divided grains in the Z direction, and the possibility of appearance of the (100) face in the X direction can be substantially reduced. In addition, an average orientation can be achieved in the X direction. Therefore, in the case of the three-dimensional cell structure, variations in polarization among the cells can be substantially reduced.

As described above, the semiconductor storage device according to this embodiment can achieve desired polarization characteristics of the ferroelectric capacitors.

### Second Embodiment

In the semiconductor storage device 100 in the first embodiment, the pedestal electrode is used to improve the margin for misalignment.

However, the pedestal electrode may be omitted as required. If the pedestal electrode is omitted, the manufacturing process can be simplified.

Thus, in a second embodiment, a configuration of the semiconductor storage device 100 in the first embodiment in which the pedestal electrode is omitted will be described.

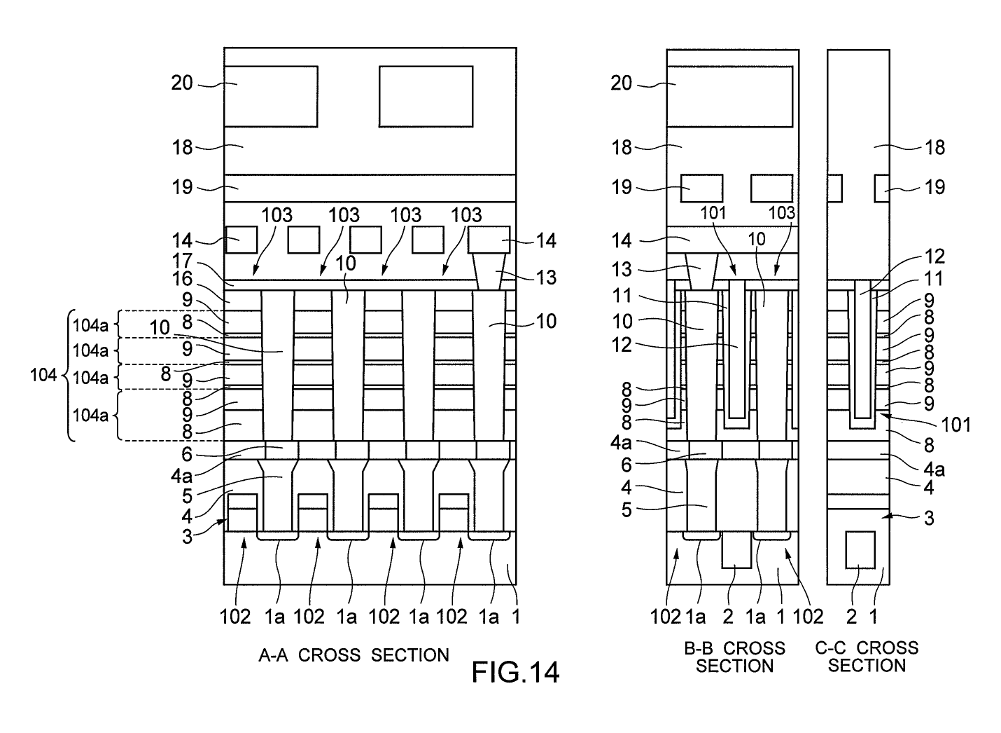

FIG. 14 includes cross-sectional views of a ferroelectric capacitor and its vicinity of a memory cell of a semiconductor storage device 200 according to the second embodiment of the present invention. The plan view of the semiconductor storage device 200 is as shown in FIG. 1 illustrating the first embodiment, and FIG. 14 includes cross-sectional views taken along the lines A-A, B-B and C-C in FIG. 1. In FIG. 14, the same components as those in the first embodiment are denoted by the same reference numerals as those in FIGS. 1 and 2.

As shown in FIG. 14, the semiconductor storage device 200 differs from the semiconductor storage device 100 shown in FIG. 2 in that the pedestal electrode 7 composed of a stack structure TiAIN/Ir is omitted. Thus, the number of steps and the cost are reduced. For example, the configuration according to the second embodiment is adopted when reducing the number of steps have higher priority than reducing the possibility of contact failure.

The remainder of the configuration of the semiconductor storage device 200 is the same as that of the semiconductor storage device 100 according to the first embodiment and has the same effects and advantages as in the first embodiment.

That is, in the second embodiment, as in the first embodiment described above, the capacitor film 104 includes a stack of a plurality of films 104a each including the insulating film 8 serving as a seed layer and the ferroelectric film 9 that is formed on the insulating film 8 to be oriented in a direction perpendicular to the semiconductor substrate 1.

As a result, the semiconductor storage device 200 has divided grains in the Z direction, and the possibility of appearance of the (100) face in the X direction can be substantially reduced. In addition, an average orientation can be achieved in the X direction. Therefore, in the case of the three-dimensional cell structure, variations in polarization among the cells can be substantially reduced.

As described above, the semiconductor storage device according to this embodiment can achieve desired polarization characteristics of the ferroelectric capacitors.

What is claimed is:

1. A semiconductor storage device, comprising:
a Metal Oxide Semiconductor (MOS) transistor on a semiconductor substrate; and
a ferroelectric capacitor above the MOS transistor and connected in parallel with the MOS transistor,
wherein the ferroelectric capacitor comprises:
a capacitor film above the MOS transistor with an interlayer insulating film therebetween;
a first capacitor electrode electrically connected to a source region of the MOS transistor and in contact with a first side wall of the capacitor film; and
a second capacitor electrode electrically connected to a drain region of the MOS transistor and in contact with a second side wall of the capacitor film, and
the capacitor film is composed of a film stack comprising a plurality of films comprising a first insulating film in order to orient a film on an upper surface thereof in a predetermined direction and a ferroelectric film on the first insulating film to be oriented in a direction perpendicular to the semiconductor substrate.

2. The semiconductor storage device of claim 1, wherein the ferroelectric film is <1, 1, 1>-oriented, <1, 0, 0>-oriented or <0, 1, 0>-oriented in the direction perpendicular to the semiconductor substrate.

3. The semiconductor storage device of claim 1, wherein a second insulating film comprising a dielectric constant lower than a dielectric constant of the ferroelectric film is formed between the capacitor films of adjacent ferroelectric capacitors connected in parallel with adjacent MOS transistors isolated from each other by a device isolation insulating film.

4. The semiconductor storage device of claim 2, wherein a second insulating film comprising a dielectric constant lower than a dielectric constant of the ferroelectric film is formed between the capacitor films of adjacent ferroelectric capacitors connected in parallel with adjacent MOS transistors isolated from each other by a device isolation insulating film.

5. The semiconductor storage device of claim 1, further comprising:
a first plug on the source region of the MOS transistor;
a second plug on the drain region of the MOS transistor;
a first pedestal electrode on the first plug comprising a diameter than a diameter of the first plug; and
a second pedestal electrode on the second plug comprising a diameter larger than a diameter of the second plug,
wherein the first capacitor electrode is on the first pedestal electrode, and
the second capacitor electrode is on the second pedestal electrode.

6. The semiconductor storage device of claim 2, further comprising:
a first plug on the source region of the MOS transistor;
a second plug on the drain region of the MOS transistor;
a first pedestal electrode on the first plug comprising a diameter larger than a diameter of the first plug; and
a second pedestal electrode on the second plug comprising a diameter larger than a diameter of the second plug,
wherein the first capacitor electrode is on the first pedestal electrode, and
the second capacitor electrode is on the second pedestal electrode.

7. The semiconductor storage device of claim 3, further comprising:
a first plug on the source region of the MOS transistor;
a second plug on the drain region of the MOS transistor;
a first pedestal electrode on the first plug comprising a diameter larger than a diameter of the first plug; and
a second pedestal electrode on the second plug comprising a diameter larger than a diameter of the second plug,
wherein the first capacitor electrode is on the first pedestal electrode, and
the second capacitor electrode is on the second pedestal electrode.

8. The semiconductor storage device of claim 4, further comprising:
a first plug on the source region of the MOS transistor;
a second plug on the drain region of the MOS transistor;
a first pedestal electrode on the first plug comprising a diameter larger than a diameter of the first plug; and
a second pedestal electrode on the second plug comprising a diameter larger than a diameter of the second plug,
wherein the first capacitor electrode is on the first pedestal electrode, and
the second capacitor electrode is on the second pedestal electrode.

9. The semiconductor storage device of claim 1, wherein the ferroelectric film is either a lead zirconate titanate (PZT) film, a BIT film, a BLT film or an SBT film.

10. The semiconductor storage device of claim 2, wherein the ferroelectric film is either PZT (Pb(ZrₓTi₁₋ₓ)O₃) film, a BIT (Bi₄Ti₃O₁₂) film, a BLT (Bi_{3.25}La_{0.75}Ti₃O₁₂) film, or an SBT (SrBi₂Ta₂O₉) film.

11. The semiconductor storage device of claim 3, wherein the ferroelectric film is either a PZT film, a BIT film, a BLT film or an SBT film.

12. The semiconductor storage device of claim 4, wherein the ferroelectric film is either a PZT film, a BIT film, a BLT film or an SBT film.

13. The semiconductor storage device of claim 5, wherein the ferroelectric film is either a PZT film, a BIT film, a BLT film or an SBT film.
